(19) United States
(12) Patent Application Publication
(10) Pub. No.: US 2026/0106617 A1
(43) Pub. Date: Apr. 16, 2026

(54) SYNCHRONIZED SWITCH MANAGEMENT SYSTEM

(71) Applicant: Connor Williams, Corvallis, OR (US)

(72) Inventor: Connor Williams, Corvallis, OR (US)

(21) Appl. No.: 18/913,454

(22) Filed: Oct. 11, 2024

(51) Int. Cl. H03K 17/97

(52) U.S. Cl. CPC H03K 17/97; H03K 2017/9706

(57) ABSTRACT

A system and method of a synchronized switch management system that synchronizes the flippers of switches. The method includes receiving, via a traveler wire, a voltage indicative of a first flipper of a first switch toggling from a first state to a second state. The method includes generating a magnetic field based on the first voltage. The method includes using the magnetic field to cause a second flipper of a second switch to toggle into a same state as the second state.

### TECHNICAL FIELD

The present disclosure relates generally to the field of electronics, and more particularly, to a synchronized switch management system that detects when a first switch is toggled into a particular state and causes a second switch to toggle into the same state to ensure that the switches maintain synchronized states.

### BACKGROUND

A switch is an electrical component that can disconnect or connect the conducting path in an electrical circuit, interrupting the electric current or diverting it from one conductor to another. A common type of switch is an electromechanical device consisting of one or more sets of movable electrical contacts connected to external circuits. When a pair of contacts is touching current can pass between them, while when the contacts are separated no current can flow. Switches are installed all throughout buildings to allow users to toggle electrical fixtures, such as lights and fans between ON and OFF states.

### BRIEF DESCRIPTION OF THE DRAWINGS

The present disclosure is illustrated by way of example, and not by way of limitation, in the figures of the accompanying drawings in which like reference numerals refer to similar elements and in which:

FIG. 1 illustrates a block diagram of an example environment of a synchronized switch management (SSM) system that uses a magnetic plunger to synchronize the states of a pair of switches of the SSM system, according to some embodiments;

FIG. 2 illustrates a block diagram of an example environment of a synchronized switch management (SSM) system that uses a magnetic device to synchronize the states of a pair of magnetized switches of the SSM system, according to some embodiments; and

FIG. 3 is a flow diagram of a procedure for using an SSM system to detect when a first switch is toggled into a particular state and causes a second switch to toggle into the same state to ensure that the switches maintain synchronized states, according to some embodiments.

### DETAILED DESCRIPTION

The following description sets forth numerous specific details such as examples of specific systems, components, methods, and so forth, in order to provide a good understanding of various embodiments of the techniques described herein for detecting when a first switch is toggled into a particular state and causing a second switch to toggle into the same state to ensure that the switches maintain synchronized states. It will be apparent to one skilled in the art, however, that at least some embodiments may be practiced without these specific details. In other instances, well-known components, elements, or methods are not described in detail or are presented in a simple block diagram format in order to avoid unnecessarily obscuring the techniques described herein. Thus, the specific details set forth hereinafter are merely exemplary. Particular implementations may vary from these exemplary details and still be contemplated to be within the scope of the present disclosure.

In an illustrative embodiment, a switch controller coupled to a second switch receives, via a traveler wire, a voltage indicative of a first flipper of a first switch toggling from a first state to a second state. The switch controller generates a magnetic field based on the first voltage. The switch controller uses the magnetic field to cause a second flipper of a second switch to toggle into a same state as the second state.

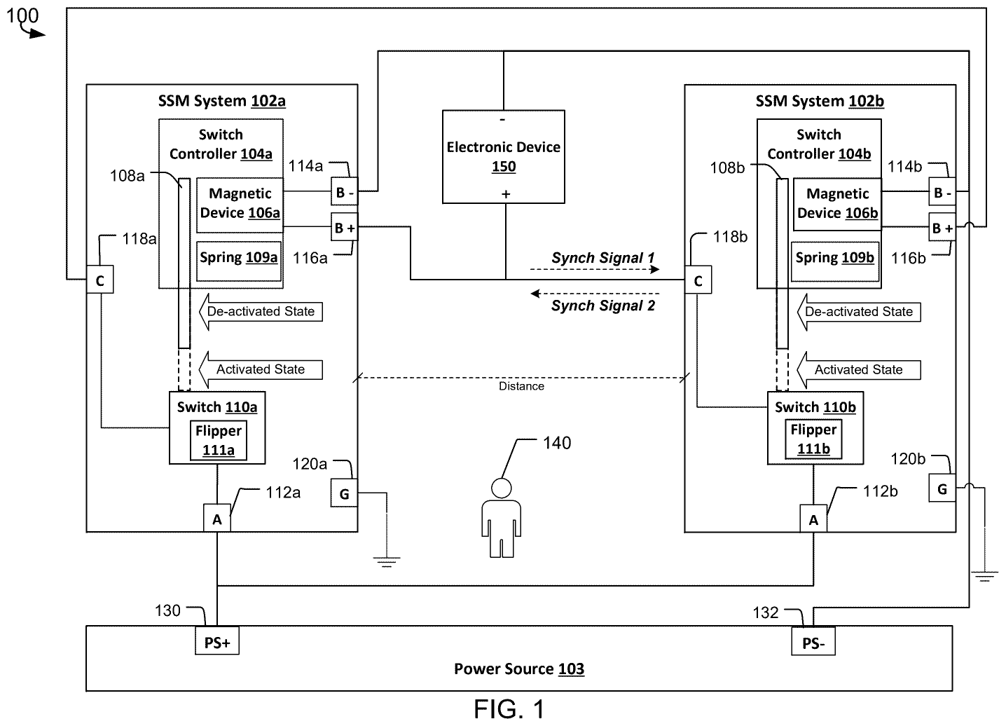

FIG. 1 illustrates a block diagram of an example environment of a synchronized switch management (SSM) system that uses a magnetic plunger to synchronize the states of a pair of switches of the SSM system, according to some embodiments. The environment 100 includes an SSM system 102a and a SSM system 102b. The environment 100 includes an electronic device 150 (e.g., light fixture, electric appliance, fan, oven, microwave, heater, air conditioner, and/or the like). The environment 100 includes one or more users 140 that can physically interact (e.g., touch) with the SSM system 102a and the SSM system 102b.

The environment 100 includes a power source 103. The power source 103 includes a positive terminal 130 (sometimes also referred to as positive terminal PS +) and a negative terminal 132 (sometimes also referred to as negative terminal PS−).

The SSM system 102a includes a switch controller 104a and a switch 110a. The switch controller 104b includes a magnetic device 106a (sometimes referred to as a state detector), a magnetic plunger 108a, and a spring 109a.

The spring 109a is coupled to the magnetic plunger 108a and maintains the magnetic plunger 108a in a deactivated state, as discussed herein. In some embodiments, the spring 109a maintains the magnetic plunger 108a in an activated state, as discussed herein, instead of the deactivated state.

The SSM system 102a includes terminal 112a (sometimes also referred to as terminal A), terminal 114a (sometimes also referred to as terminal B −), terminal 116a (sometimes also referred to as terminal B +), terminal 118a (sometimes also referred to as terminal C), and terminal 120a (sometimes also referred to as ground terminal).

The SSM system 102b includes a switch controller 104b and a switch 110b. The switch controller 104b includes a magnetic device 106b, a magnetic plunger 108b, and a spring 109b.

The spring 109b is coupled to the magnetic plunger 108b and maintains the magnetic plunger 108b in a deactivated state, as discussed herein. In some embodiments, the spring 109b maintains the magnetic plunger 108b in an activated state, as discussed herein, instead of the deactivated state.

The SSM system 102b includes terminal 112b (sometimes also referred to as terminal A), terminal 114b (sometimes also referred to as terminal B −), terminal 116b (sometimes also referred to as terminal B +), terminal 118b (sometimes also referred to as terminal C), and terminal 120b (sometimes also referred to as ground terminal).

The positive terminal 130 (PS+) of the power source 103 is electrically coupled to terminal 112a of SSM system 102a. Terminal 112a is electrically coupled to a first terminal of the switch 110a, whose second terminal is electrically coupled to terminal 118a of SSM system 102a. Terminal 118a of SSM system 102a is electrically coupled to terminal 116b of SSM system 102b. In some embodiments, terminal 118a of SSM system 102a and terminal 116b of SSM system 102b are electrically coupled via a traveler (sometimes referred to as traveler wire) that is partially or completely hidden behind one or more walls of a building.

Terminal 116a of SSM system 102a is electrically coupled to a positive terminal of the electronic device 150 and terminal 118b of SSM system 102b. The terminal 118b is electrically coupled to the positive terminal of the electronic device 150. Terminal 118b of SSM system 102b is electrically coupled to a second terminal of switch 110b, whose first terminal is electrically coupled to terminal 112b of SSM system 102b. Terminal 112b of SSM system 102b is electrically coupled to the positive terminal of the power source 103. Thus, the power source 103 provides positive power to both the SSM system 102 and the SSM system 102b.

Terminal 114a of SSM system 102a is electrically coupled to a negative terminal of electronic device 150, terminal 114b of SSM system 102b, and the negative terminal 132 of the power source 103.

A positive terminal of the magnetic device 106a of the SSM system 102a is electrically coupled to terminal 116a of the SSM system 102a and a negative terminal of the magnetic device 106a of the SSM system 102a is electrically coupled to terminal 114a of the SSM system 102a.

A positive terminal of the magnetic device 106b of the SSM system 102b is electrically coupled to terminal 116b of the SSM system 102b and a negative terminal of the magnetic device 106b of the SSM system 102b is electrically coupled to terminal 114b of the SSM system 102b.

In some embodiments, the SSM system 102a may be attached (e.g., installed, adhered) to a wall of a building and the SSM system 102b may be attached to the same wall or a different wall. In some embodiments, the SSM system 102a may be located in the same room of a building or in different rooms of the building. In some embodiments, the SSM system 102a may be located on a particular floor of a building, while the SSM system 102b is located on a different floor of the same building. In some embodiments, the SSM system 102a and SSM system 102a are physically separated from each other by a distance that is within the range of, for example, 1 foot to 1000 feet.

Each switch 110 (e.g., switch 110a, switch 110b) may each include a flipper 111 (e.g., flipper 111a, flipper 111b) that is configured to activate (e.g., short the terminals of the switch together) or deactivate the switch depending on the physical position of the flipper 111. In some embodiments, a flipper 111 may be a rocker or a button instead of a flipper. The flipper 111 protrudes from the switch 110 so to allow a user 140 to physically toggle the flipper 111 from a first position (e.g., up) corresponding to first switch state (e.g., activated) for the switch 110 to a second position (e.g., down) corresponding to a second switch state (e.g., deactivated) for the switch 110. In some embodiments, the logic is reversed such that the ‘up’ position of the flipper 111 corresponds to the second switch state (e.g., deactivated) and the ‘down’ position of the flipper 111 corresponds to the first switch state (e.g., activated).

Terminals 120a, 120b are each coupled to earth ground.

Still referring to FIG. 1, the user 140 toggles the flipper 111b from a first position (e.g., down) corresponding to an open state (e.g., OFF) of the switch 110b to a second position (e.g., up) corresponding to a closed state (e.g., ON) of the switch 110b, which causes the two terminals of the switch 110b to electrically short together.

Closing the switch 110b allows the power source 103 to provide the P+ voltage from its positive terminal 130 to the positive terminal of the magnetic device 106a of the SSM system 102a, which activates (e.g., enables) the magnetic device 106b to cause it to generate a magnetic field radiating toward the magnetic plunger 108a. The magnetic field forces the magnetic plunger 108a to physically move from a first position where the magnetic plunger 108a is not physically contacting the flipper 111a and corresponding to a de-activated state (e.g., disabled) to a second position where the magnetic plunger 108a is physically contacting the flipper 111a and corresponding to an activated state. That is, when entering into the activated state, the magnetic plunger 108a pushes against the flipper 111a to cause the flipper 111a to toggle from a first position (e.g., down) corresponding to an open state (e.g., OFF) of the switch 110a to a second position (e.g., up) corresponding to a closed state (e.g., ON) of the switch 110a, which in turn, causes the two terminals of the switch 110a to electrically short together.

Closing the switch 110b allows the power source 103 to provide the P+ voltage from its positive terminal 130 to the positive terminal of the electronic device 150, which activates the electronic device 150. For example, the electronic device 150 may be a lightbulb, so closing switch 110b turns on the lightbulb. Thus, flipper 111a and flipper 111b are both in the same position (e.g., up) when the electronic device 150 is activated.

Alternatively, the user 140 (e.g., the same user or a different user) may toggle the switch 110b back into the first position (e.g., down) corresponding to an open state (e.g., OFF) of the switch 110b, which causes the two terminals of the switch 110b to electrically open. This removes the P+ voltage from the positive terminal of the magnetic device 106a of the SSM system 102a, which de-activates (e.g., disables) the magnetic device 106b to cause it to stop generating the magnetic field radiating toward the magnetic plunger 108a. Without the magnetic field, the magnetic plunger 108a physically moves back to the first position where the magnetic plunger 108a is not physically contacting the flipper 111a and corresponding to a de-activated state (e.g., disabled). That is, when entering into the de-activated state, the magnetic plunger 108a is no longer pushing against the flipper 111a, so the spring 109a is free to move the flipper 111a back into the first position (e.g., down) corresponding to an open state (e.g., OFF) of the switch 110a, which causes the two terminals of the switch 110a to electrically open.

Opening the switch 110b removes the P+ voltage from the positive terminal of the electronic device 150, which de-activates the electronic device 150. For example, the electronic device 150 may be a lightbulb, so opening switch 110b turns off the lightbulb. Thus, flipper 111a and flipper 111b are both in the same position (e.g., down) when the electronic device 150 is deactivated.

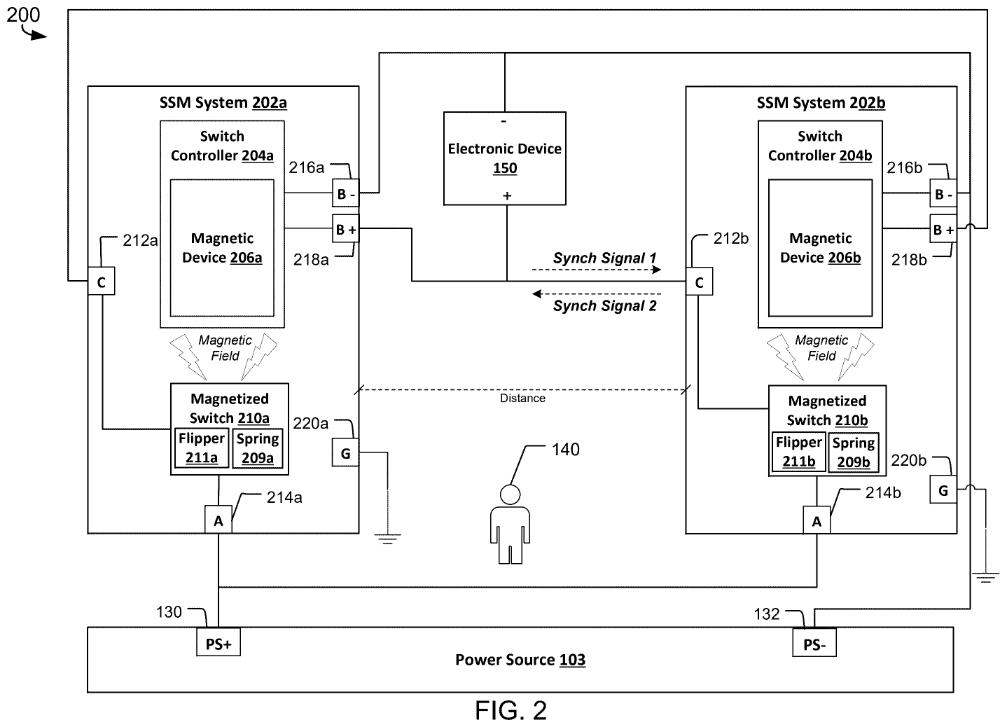

FIG. 2 illustrates a block diagram of an example environment of a synchronized switch management (SSM) system that uses a magnetic device to synchronize the states of a pair of magnetized switches of the SSM system, according to some embodiments. The environment 200 includes an SSM system 202a and a SSM system 202b. The environment 200 includes the electronic device 150 in FIG. 1. The environment 200 includes one or more users 140 that can physically interact (e.g., touch) with the SSM system 202a and the SSM system 202b.

The environment 200 includes the power source 103 in FIG. 1.

The SSM system 202a includes a switch controller 204a and a magnetized switch 210a that has a positive polarity or negative polarity. The magnetized switch 210a includes a flipper 211a that either activates or deactivates the switch based on the position of the flipper 211a. The magnetized switch 210a includes a spring 209a that is coupled to the flipper 211a and configured to maintain the flipper 211a in an activated state or deactivated state. The switch controller 204a includes a magnetic device 206a that can generate a magnetic field that has a positive polarity or negative polarity to control the position of flipper 211a on the magnetized switch 210a.

The SSM system 202a includes terminal 212a (sometimes also referred to as terminal A), terminal 214a (sometimes also referred to as terminal B −), terminal 216a (sometimes also referred to as terminal B +), terminal 218a (sometimes also referred to as terminal C), and terminal 220a (sometimes also referred to as ground terminal).

The SSM system 202b includes a switch controller 204b and a magnetized switch 210b that has a positive polarity or negative polarity. The magnetized switch 210b includes a flipper 211b that either activates or deactivates the magnetized switch based on the position of the flipper 211b. The magnetized switch 210b includes a spring 209b that is coupled to the flipper 211b and configured to maintain the flipper 211b in an activated state or deactivated state. The switch controller 204b includes a magnetic device 206b that can generate a magnetic field that has a positive polarity or negative polarity to control the position of flipper 211b on the magnetized switch 210b.

The SSM system 202b includes terminal 212b (sometimes also referred to as terminal A), terminal 214b (sometimes also referred to as terminal B −), terminal 216b (sometimes also referred to as terminal B +), terminal 218b (sometimes also referred to as terminal C), and terminal 220b (sometimes also referred to as ground terminal).

The positive terminal 130 (PS+) of the power source 103 is electrically coupled to terminal 212a of SSM system 202a. Terminal 212a is electrically coupled to a first terminal of the magnetized switch 210a, whose second terminal is electrically coupled to terminal 218a of SSM system 202a. Terminal 218a of SSM system 202a is electrically coupled to terminal 216b of SSM system 202b. In some embodiments, terminal 218 of SSM system 202a and terminal 216b of SSM system 202b are electrically coupled via a traveler that is partially or completely hidden behind one or more walls of a building.

Terminal 216a of SSM system 202a is electrically coupled to a negative terminal of the electronic device 150 and terminal 218b of SSM system 202b.

Terminal 218b of SMM system 202b is electrically coupled to a second terminal of magnetized switch 210b, whose first terminal is electrically coupled to terminal 212b of SSM system 202b. Terminal 212b of SSM system 202b is electrically coupled to the positive terminal of the power source 103. Thus, the power source 103 provides positive power to both the SSM system 202 and the SSM system 202b.

Terminal 214a of SSM system 202a is electrically coupled to a negative terminal of electronic device 150, terminal 214b of SSM system 202b, and the negative terminal 132 of the power source 103.

A positive terminal of the magnetic device 206a of the SSM system 202a is electrically coupled to terminal 216a of the SSM system 202a and a negative terminal of the magnetic device 206a of the SSM system 202a is electrically coupled to terminal 214a of the SSM system 202a.

A positive terminal of the magnetic device 206b of the SSM system 202b is electrically coupled to terminal 216b of the SSM system 202b and a negative terminal of the magnetic device 206b of the SSM system 202b is electrically coupled to terminal 214b of the SSM system 202b.

In some embodiments, the SSM system 202a may be attached (e.g., installed, adhered) to a wall of a building and the SSM system 202b may be attached to the same wall or a different wall. In some embodiments, the SSM system 202a may be located in the same room of a building or in different rooms of the building. In some embodiments, the SSM system 202a may be located on a particular floor of a building, while the SSM system 202b is located on a different floor of the same building. In some embodiments, the SSM system 202a and SSM system 202a are physically separated from each other by a distance that is within the range of, for example, 1 foot to 1000 feet.

Each flipper 211 (e.g., flipper 211a, flipper 211b) is configured to activate (e.g., short the terminals of the magnetized switch together) or deactivate its corresponding magnetized switch 210 depending on the physical position of the flipper 211. In some embodiments, a flipper 211 may be a rocker or a button instead of a flipper. The flipper 211 protrudes from the magnetized switch 210 so to allow a user 140 to physically toggle the flipper 211 from a first position (e.g., up) corresponding to first switch state (e.g., activated) for the magnetized switch 210 to a second position (e.g., down) corresponding to a second switch state (e.g., deactivated) for the magnetized switch 210. In some embodiments, the logic is reversed such that the ‘up’ position of the flipper 211 corresponds to the second switch state (e.g., deactivated) and the ‘down’ position of the flipper 211 corresponds to the first switch state (e.g., activated).

Terminals 220a, 220b are each coupled to earth ground.

Still referring to FIG. 2, the user 140 toggles the flipper 211b from a first position (e.g., down) corresponding to an open state (e.g., OFF) of the magnetized switch 210b to a second position (e.g., up) corresponding to a closed state (e.g., ON) of the magnetized switch 210b, which causes the two terminals of the magnetized switch 210b to electrically short together.

Closing the magnetized switch 210b allows the power source 103 to provide the P+ voltage from its positive terminal 130 to the positive terminal of the magnetic device 206a of the SSM system 202a, which activates (e.g., enables) the magnetic device 206b to cause it to generate a magnetic field radiating toward the magnetized switch 210a. The magnetic field forces the flipper 211a of the magnetized switch 210a to toggle from a first position (e.g., down) corresponding to an open state (e.g., OFF) of the magnetized switch 210a to a second position (e.g., up) corresponding to a closed state (e.g., ON) of the magnetized switch 210a, which in turn, causes the two terminals of the magnetized switch 210a to electrically short together.

Closing the magnetized switch 210b allows the power source 103 to provide the P+ voltage from its positive terminal 130 to the positive terminal of the electronic device 150, which activates the electronic device 150. For example, the electronic device 150 may be a lightbulb, so closing magnetized switch 210b turns on the lightbulb. Thus, flipper 211a and flipper 211b are both in the same position (e.g., up) when the electronic device 150 is activated.

Alternatively, the user 140 (e.g., the same user or a different user) may toggle the magnetized switch 210b back into the first position (e.g., down) corresponding to an open state (e.g., OFF) of the magnetized switch 210b, which causes the two terminals of the magnetized switch 210b to electrically open. This removes the P+ voltage from the positive terminal of the magnetic device 206a of the SSM system 202a, which de-activates (e.g., disables) the magnetic device 206b to cause it to stop generating the magnetic field radiating toward the magnetized switch 210b. Without the magnetic field, the spring 209a is free to move the flipper 211a back into the first position (e.g., down) corresponding to an open state (e.g., OFF) of the magnetized switch 210a, which causes the two terminals of the magnetized switch 210a to electrically open.

Opening the magnetized switch 210b removes the P+ voltage from the positive terminal of the electronic device 150, which de-activates the electronic device 150. For example, the electronic device 150 may be a lightbulb, so opening magnetized switch 210b turns off the lightbulb. Thus, flipper 211a and flipper 211b are both in the same position (e.g., down) when the electronic device 150 is deactivated.

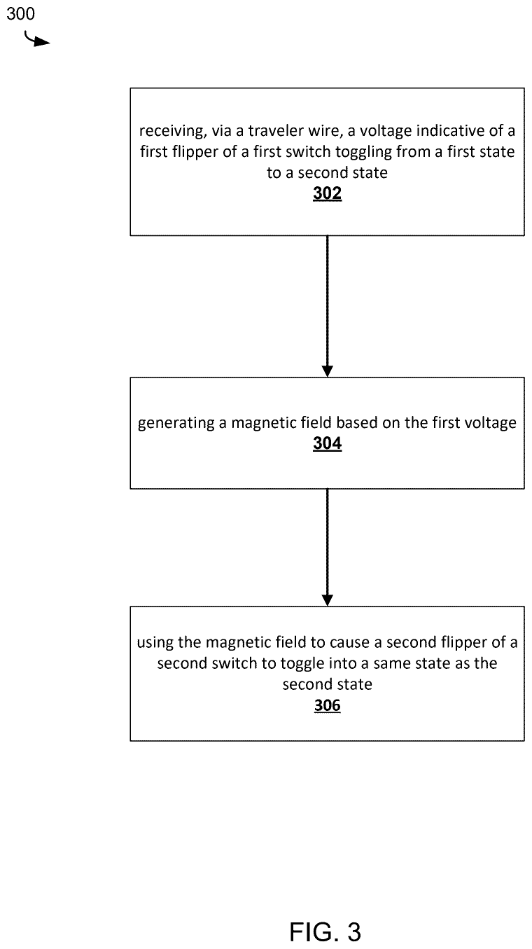

FIG. 3 is a flow diagram of a procedure for using an SSM system to detect when a first switch is toggled into a particular state and causes a second switch to toggle into the same state to ensure that the switches maintain synchronized states, according to some embodiments. Although the operations are depicted in FIG. 3 as integral operations in a particular order for purposes of illustration, in other implementations, one or more operations, or portions thereof, are performed in a different order, or overlapping in time, in series or parallel, or are omitted, or one or more additional operations are added, or the method is changed in some combination of ways. In some embodiments, the procedure 300 may be performed by processing logic that includes hardware (e.g., circuitry, dedicated logic, programmable logic, microcode, etc.), firmware, or a combination thereof.

The procedure 300 will be described with respect to the components (e.g., SSM system 102a, SSM system 102b, electronic device 150, power source 103) in environment 100, but may also be implemented using any of the components of the environment in FIG. 2. At operation 902, in some embodiments, the SSM system 102a receives, from the SSM system 102b via a traveler wire, a voltage indicative (sometimes referred to as a synchronization signal) of a first flipper (e.g., flipper 111b) of a first switch (e.g., switch 110b) toggling from a first state to a second state. At operation 904, in some embodiments, the SSM system 102b generates a magnetic field based on the first voltage. At operation 904, in some embodiments, the SSM system 102b uses the magnetic field to cause a second flipper (e.g., flipper 111a) of a second switch (e.g., switch 110a) to toggle into a same state as the second state.

In the above description, some portions of the detailed description are presented in terms of algorithms and symbolic representations of operations on analog signals and/or digital signals or data bits within a non-transitory storage medium. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the disclosure. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. It should be understood that the embodiments described herein are not intended to limit the scope of the subject matter but rather to enable one skilled in the art to practice, make, and/or use the subject matter.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “generating,” “using,” “applying,” “eliminating” or the like, refer to the actions and processes of an integrated circuit (IC) controller, or similar electronic device, that manipulates and transforms data represented as physical (e.g., electronic) quantities within the controller's registers and memories into other data similarly represented as physical quantities within the controller memories or registers or other such information non-transitory storage medium.

The words “example” or “exemplary” are used herein to mean serving as an example, instance, or illustration. Any aspect or design described herein as “example′ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B”is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments described herein may also relate to an apparatus (e.g., such as an AC-DC converter, and/or an ESD protection system/circuit) for performing the operations herein. This apparatus may be specially constructed for the required purposes, or it may include firmware or hardware logic selectively activated or reconfigured by the apparatus. Such firmware may be stored in a non-transitory computer-readable storage medium, such as, but not limited to, read-only memories (ROMs), random access memories (RAMs), EPROMs, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The above description sets forth numerous specific details such as examples of specific systems, components, methods, and so forth, in order to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed IS:

1. A method comprising:
receiving, via a traveler wire, a first voltage indicative of a first flipper of a first switch toggling from a first state to a second state;
generating a magnetic field based on the first voltage; and
using the magnetic field to cause a second flipper of a second switch to toggle into a same state as the second state.

2. The method of claim 1, wherein the first voltage activates at least one of a lightbulb, a fan, or an electric appliance.

3. The method of claim 1, wherein using the magnetic field to cause the second flipper of the second switch to toggle into the same state as the second state further comprising:
applying the magnetic field to a magnetic plunger to cause the magnetic plunger to physically connect with the second flipper and move the second flipper into the same state as the second state.

4. The method of claim 1, wherein using the magnetic field to cause the second flipper of the second switch to toggle into the same state as the second state further comprising:
applying the magnetic field to the second flipper to cause the second flipper to repel away from the magnetic field.

5. The method of claim 1, wherein the first switch and the second switch are physically separated by a distance that is greater than 2 feet.

6. The method of claim 1, wherein the second flipper is coupled to a spring that applies a force in an opposite direction of the magnetic field.

7. The method of claim 6, further comprising:
receiving, via the traveler wire, a second voltage indicative of the first flipper of the first switch toggling from the second state to the first state; and
eliminating the magnetic field responsive to receiving the second voltage to allow the spring to toggle the second flipper of the second switch into a same state as the first state.

8. A synchronized switch management (SSM) system, comprising:
a second switch comprising a second flipper; and
a switch controller to:
receive, via a traveler wire, a first voltage indicative of a first flipper of a first switch toggling from a first state to a second state;
generate a magnetic field based on the first voltage; and
use the magnetic field to cause the second flipper of the second switch to toggle into a same state as the second state.

9. The SSM system of claim 8, wherein the first voltage activates at least one of a lightbulb, a fan, or an electric appliance.

10. The SSM of claim 8, further comprising:
a magnetic plunger coupled to the switch controller, wherein to use the magnetic field, the switch controller is further to:
apply the magnetic field to the magnetic plunger to cause the magnetic plunger to physically connect with the second flipper and move the second flipper into the same state as the second state.

11. The SSM of claim 8, wherein to use the magnetic field, the switch controller is further to:
apply the magnetic field to the second flipper to cause the second flipper to repel away from the magnetic field.

12. The SSM of claim 8, wherein the first switch and the second switch are physically separated by a distance that is greater than 2 feet.

13. The SSM of claim 8, further comprising:
a spring coupled to the second flipper, wherein the spring is to apply a force in an opposite direction of the magnetic field.

14. The SSM of claim 13, wherein the switch controller is further to:
receive, via the traveler wire, a second voltage indicative of the first flipper of the first switch toggling from the second state to the first state; and
eliminate the magnetic field responsive to receiving the second voltage to allow the spring to toggle the second flipper of the second switch into a same state as the first state.

15. A synchronized switch management (SSM) system, comprising:
a first SSM device comprising:
a first switch coupled to a first flipper; and
a first external port to provide a first voltage indicative of the first flipper toggling from a first state to a second state;
a second SSM device comprising:
a second external port coupled to the first external port of the first SSM device via a traveler wire, the second external port is to receive the first voltage via the traveler wire;
a second switch comprising a second flipper; and
a switch controller to generate a magnetic field based on the first voltage and use the magnetic field to cause the second flipper of the second switch to toggle into a same state as the second state.

16. The SSM of claim 15, wherein the first SSM device further comprises:
a magnetic plunger coupled to the switch controller, wherein to use the magnetic field, the switch controller is further to:
apply the magnetic field to the magnetic plunger to cause the magnetic plunger to physically connect with the second flipper and move the second flipper into the same state as the second state.

17. The SSM of claim 15, wherein to use the magnetic field, the switch controller is further to:
apply the magnetic field to the second flipper to cause the second flipper to repel away from the magnetic field.

18. The SSM of claim 15, wherein the first switch and the second switch are physically separated by a distance that is greater than 2 feet.

19. The SSM of claim 15, wherein the second SSM device further comprises:
a spring coupled to the second flipper, wherein the spring is to apply a force in an opposite direction of the magnetic field.

20. The SSM of claim 19, wherein the switch controller is further to:
receive, via the traveler wire, a second voltage indicative of the first flipper of the first switch toggling from the second state to the first state; and
eliminate the magnetic field responsive to receiving the second voltage to allow the spring to toggle the second flipper of the second switch into a same state as the first state.
